(19) United States
(12) Patent Application Publication
(10) Pub. No.: US 2023/0359777 A1
(43) Pub. Date: Nov. 9, 2023

(54) Systems and Methods for Designing a Theater Room

(71) Applicant: Audio Advice, Inc., Raleigh, NC (US)

(72) Inventors: Scott Gaither Newnam, Morrisville, NC (US); Leon Whitfield Shaw, Wake Forest, NC (US); Jonathan Daniel Stephens, Raleigh, NC (US); Heather Wray McMillen, Clayton, NC (US)

(21) Appl. No.: 17/736,288

(22) Filed: May 4, 2022

(51) Int. Cl. G06F 30/12; G06F 30/13; H04R 5/02

(52) U.S. Cl. CPC G06F 30/12; G06F 30/13; H04R 5/02; H04R 2205/024

(57) ABSTRACT

Systems and methods for displaying a graphical user interface that represents an arrangement of components in a room. Based on inputs from the user and/or default settings regarding one or more of the components, a visual representation of the room is generated for outputting to view on a display screen of s user device. The graphical user interface facilitates a user in designing and selecting components for the room.

### TECHNOLOGICAL FIELD

The present disclosure relates generally to the design of a room and, more specifically, to design of a room that provides for generating a graphical user interface that represents a room and calculations for determining the placement of the various components within the room to enhance video and/or audio performance.

### BACKGROUND

Various rooms are designed to provide viewers with a heightened audio and visual performance. An example includes rooms designed exclusively for a theatrical experience and I've commonly referred to as theater rooms. Another example includes media rooms that are a more general space designed to watch sports, movies, and/or listening to music. The rooms can be designed to include a variety of different user-selected components including various speakers, display screens, seats, and projectors. An issue with designing a room is selecting the components and then positioning the components in the room. Often times a design is lacking because of the selection of the components and/or the placement of the components.

Design of a room can also include using various combinations of components at different locations in the room. For example, the design process can try different numbers and spacing of the seats, different screen sizes, different numbers and spacing of speakers, etc. In addition, components with different sizes and styles, as well as components from different manufacturers may be tried as part of the design. Changing the type, number, and/or position of components can be a time-consuming process during the design.

Another issue is that the room design is difficult to understand in the abstract. The design can be written on paper or verbally explained, but it is often difficult for a person to fully appreciate the design. A full understanding of the design may not be appreciated until the room is created and the components installed. Unfortunately, changing the design after installation can be expensive as components may need to be replaced and/or moved within the room.

Therefore, there is a need for a room design tool that facilitates the design process to evaluate different components and different spacing. The design tool may provide a room to deliver the experience intended by producers of the content, such as a movie or show that includes special effects wherein the audio signal moves around to room to match a visual experience.

### SUMMARY

One aspect is directed to a method of generating an of an interactive graphical user interface that represents a room for viewing on a user device with the room comprising a floor, a front wall, and a screen mounted to a front wall. The method comprises: determining a first control location defining an eye height of a back viewer sitting in a back seat with the eye height comprising a first distance above the floor; determining a second control location that is above a head of a front viewer sitting in a front seat and positioned between the back seat and the screen with the second control location comprising a combination of an amount the head of the front viewer is above the floor when sitting in the front seat plus a safety variable distance; determining a viewpoint line that extends between the first control location and the screen with the viewpoint line being perpendicular to the screen; determining an angle at the first control location formed between the viewpoint line and a straight line that extends between the first control location and the second control location; based on the angle and a distance between the first control location and the screen, calculating a screen height between the floor and a bottom edge of the screen; generating an interactive graphical user interface that represents the room and comprises the back seat, the front seat, and the screen mounted to the front wall with a bottom of the screen positioned above the floor by the screen height; and outputting the graphical user interface to a display of a user device.

In another aspect, determining the first control location comprises adding a back seat height plus forty-three (43) inches.

In another aspect, the method further comprises determining the seat height of the back seat comprises the seat height=(rows−1)(riser height) where rows equals the numbers of rows and riser height equals a height of a riser above the floor.

In another aspect, determining the second control location comprises adding a front seat height plus forty-six (46) inches.

In another aspect, the safety variable distance comprises two (2) inches.

In another aspect, determining the second control location comprises the second control location=(rows−2)(riser height)+46+2 where rows equal the number of rows and riser height equal a height of a riser above the floor.

In another aspect, the method further comprises determining the first control location along the length of the room as a first predetermined distance from a back of the back seat and determining the second control location along the length of the room as a second predetermined distance from a back of the front seat.

In another aspect, the method further comprises: determining positions of speakers in the room and sound envelopes that are emitted from the speakers; generating the interactive graphical user interface comprising the sound envelopes; and outputting the graphical user interface with the sound envelopes to the display of the user device.

In another aspect, the method further comprises: receiving a first input from the user device comprising an immersion distance of a primary viewing point away from the screen along the length; receiving a second input from the user device comprising a display size of the screen; and determining an immersion level based on the immersion distance and the display type.

One aspect is directed to a server configured to generate an interactive graphical user interface that represents a room with the room comprising a floor, a front wall, a back wall, a ceiling, and a screen mounted to a front wall. The server comprises a memory circuitry configured to contain: a length of the room measured between the front and back walls; a primary viewing point along the length of the room with the primary viewing point positioned a first distance along the length away from the screen and a second distance below the ceiling; and a buffer region that extends along the length outward from the back wall. The server also comprises processing circuitry configured to: calculate a position of rear ceiling speakers along the length at an angle formed between a perpendicular line that extends from the ceiling to the primary viewing point and a first angle line; when the position is outside of the buffer region, locate the rear ceiling speakers at the position; when the position is within the buffer region, reduce the angle and recalculate the position of the rear ceiling speakers to outside of the buffer region; calculate a distance between the perpendicular line and the position; position the front ceiling speakers at a front location along the length that is in front of the perpendicular line by the distance; generate a graphical user interface of the room that comprises a row of seats at the primary viewing point with the screen mounted to the front wall, the rear ceiling speakers at the position behind primary viewing point, and the front ceiling speakers at the front location; and output the graphical user interface to a display of a user device.

In another aspect, the processing circuitry is configured to center the front ceiling speakers and the back ceiling speakers along a centerline of a width of the room.

In another aspect, the processing circuitry is configured to position the front ceiling speakers and the back ceiling speakers apart within a range of between 60°-90°.

In another aspect, the processing circuitry is configured to space each of the front ceiling speakers and the back ceiling speakers an equal distance away from the primary viewing point along the length.

In another aspect, the processing circuitry is further configured to: determine sound envelopes that are emitted from the front ceiling speakers and the back ceiling speakers; generate the graphical user interface comprising the sound envelopes; and output the graphical user interface with the sound envelopes to the display of the user device.

In another aspect, the processing circuitry is further configured to: receive a first input from the user device comprising an immersion distance of a primary viewing point away from the screen along the length; receive a second input from the user device comprising a display type of the screen; and determine an immersion level based on the immersion distance and the display type.

One aspect is directed to a server configured to generate an interactive graphical user interface that represents a room with the room comprising a floor, a front wall, a back wall, a ceiling, and a screen mounted to a front wall. The server comprises memory circuitry and processing circuitry. The processing circuitry is configured to: determine a first control location defining an eye height of a back viewer sitting in a back seat with the eye height comprising a first distance above the floor; determine a second control location defining a spot above a head of a front viewer sitting in a front seat and positioned between the back seat and the screen with the second control location comprising a combination of an amount the head of the front viewer is above the floor when sitting in the front seat plus a safety variable distance; determine a viewpoint line that extends between the first control location and the screen with the line being perpendicular to the screen; determine an angle at the first control location formed between the viewpoint line and a straight line that extends between the first control location and the second control location; based on the angle and a distance between the first control location and the screen, calculate a screen height between the floor and a bottom edge of the screen; generate an interactive graphical user interface that represents the room and comprises the back seat, the front seat, and the screen mounted to the front wall with a bottom of the screen positioned above the floor by the screen height; and output the graphical user interface to a display of a user device.

The features, functions and advantages that have been discussed can be achieved independently in various aspects or may be combined in yet other aspects, further details of which can be seen with reference to the following description and the drawings.

### BRIEF DESCRIPTION OF THE DRAWINGS

FIG. 1 is a schematic diagram of a communication network that includes a server operatively connected to user devices.

FIG. 2 is a display generated by a server with the display having a room section, an input section, and a control section.

FIG. 3 is a top view of a room image generated by a server.

FIG. 4 is a flowchart diagram of a method of generating a graphical user interface that includes a representation of a room.

FIG. 5 is a schematic diagram of a server.

FIGS. 6A and 6B are schematic side views of dimensions and calculated values for sightline calculations.

FIG. 6C is a flowchart diagram of a method of generating an of an interactive graphical user interface

FIG. 7 is a schematic diagram of a horizontal viewing angle.

FIG. 8 is a top schematic diagram of placement of rear speakers for a room.

FIG. 9 is a top schematic diagram of placements for ceiling speakers within a room.

FIG. 10 is a side schematic diagram of placement of pairs of ceiling speakers in a room.

FIG. 11 is a flowchart diagram of a method of positioning rear speakers in a room.

FIG. 12 is a perspective view of a room generated by a server with the room including sound dispersion envelopes.

FIG. 13A-13C are perspective views of a room with the components adjusted based on one or more user inputs.

### DETAILED DESCRIPTION

The present application is directed to systems and methods for displaying a graphical user interface that represents an arrangement of components in a room. Based on inputs from the user and/or default selections regarding one or more of the components, a visual representation of the room is generated and outputted for viewing on a display screen of a user device. The display facilitates a user in designing and selecting components for the room.

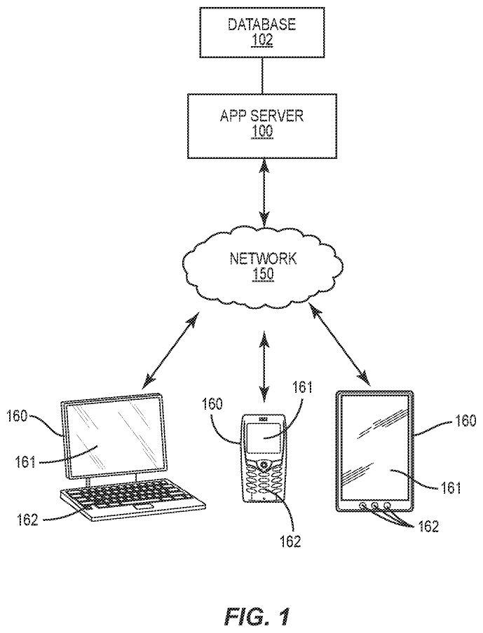

FIG. 1 illustrates an application server 100 configured to generate a graphical user interface that includes a visual representation of the room. The graphical user interface can then be displayed to a viewer on a display screen of a user device 160. The server 100 generates the room images of the interface based on one or more inputs received from one or more user devices 160 and/or default settings stored at the server 100. The server 100 includes a control program and rules and/or accesses the information from a database 102. The server 100 communicates with the user devices 160 through a wired or wireless communications network 150, such as a packet data network. The network 150 can include a public network such as the Internet, or a private network. The network 150 can also provide for communication through a mobile communication network (e.g., a WCDMA, LTE, or WiMAX network) and a Wireless Local Area Network (WLAN) that operates according to the 802.11 family of standards, which is commonly known as a WiFi interface.

In one example, the server 100 is configured to provide a web interface for access by the user devices 160. The server 100 is configured for the user to access information about the room design using a browser-based interface (e.g., Internet Explorer and Mozilla Firefox, Safari, Chrome) or an applications program interface (API). The browser-based interface can include a website through which the contents of the room design can be accessible. Although the website can be hosted by the server 100, it can also be hosted at another location accessible through the network 150.

Users can access the information at the server 100 through a variety of user devices 160. The user devices 160 can include but are not limited to laptop computers, personal computers, personal digital assistants, mobile computing/communication, tablet devices, and various other-like computing devices. Each of the users uses a respective user device 160 and accesses the server 100 through the network 150, or alternatively some other network. In one embodiment, one or more of the users can use his or her respective user device 160 to access the server 100 through a separate portal. Each user's portal can include a secure interface through which the user can access the information that is assigned to them.

Each user device 160 further includes a display 161 for displaying the room layout that is generated by the server 100. The user devices 160 further include one or more inputs 162 for the user to provide inputs to the server 100 regarding the room layout and various components.

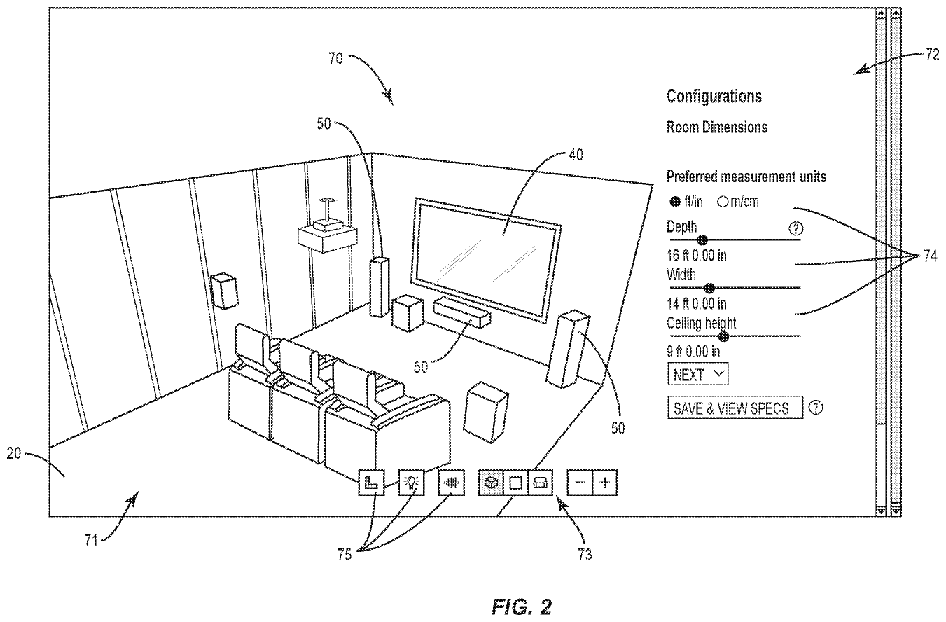

FIG. 2 illustrates an example of a graphical user interface 70 of a room 20 that is generated by the server 100 for viewing on the display 161 of a user device 160. The graphical user interface 70 generally includes multiple different sections for displaying different information to the user. A room section 71 displays the layout of the room 20. An input section 72 includes one or more inputs 74 for a user to enter data for the server 100 to generate the room 20. A control section 73 provides one or more control settings 75 for the user to change how the room 20 is displayed in the room section 71.

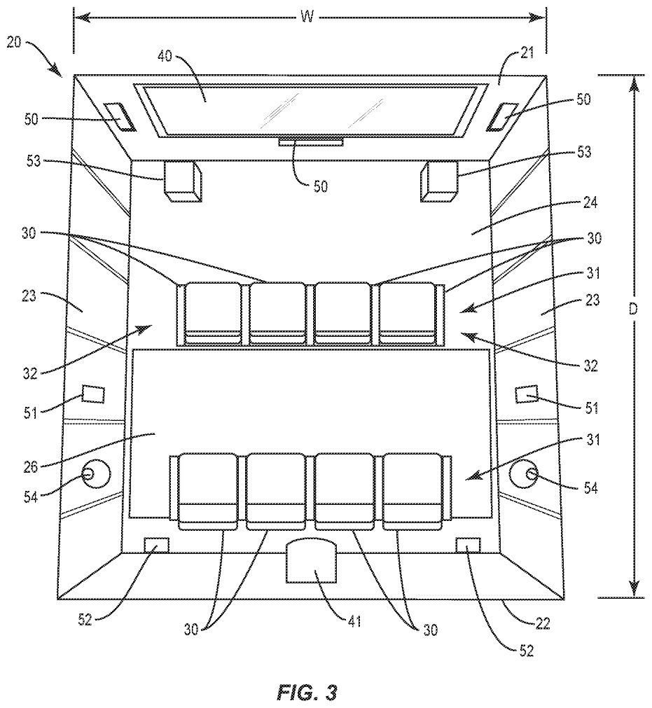

The room section 71 is a generated view of the room 20. As illustrated in FIG. 3, the generated room 20 includes outer walls that define the theater space and includes a front wall 21, a back wall 22, side walls 23, and a floor 24 (the ceiling 25 is omitted in FIG. 3 to provide a view into the interior). One or more of the outer walls may be transparent in one or more of the views. For example, the ceiling 25 is not illustrated in the perspective view of FIG. 2 or the top view of FIG. 3.

The room 20 includes dimensions that are defined by the outer walls. A depth D of the room 20 is defined between the front and back walls 21, 22. A width W of the room 20 is defined between the side walls 23. A height H of the room 20 is defined between the floor 24 and the ceiling 25. The room 20 further includes one or more seats 30. The seats 30 can be arranged in various configurations. One example includes rows 31 that are aligned in straight line. Another example includes rows 31 that are arranged in a curved configuration, L-shaped configuration, C-shaped, etc. The seats 30 can be sized to hold a single person, or two or more persons such as a couch or love seat. The room 20 also includes a screen 40 to display video/images, one or more speakers 50, 51, 52, 53, 54, and can include a projector 41.

The server 100 generates the room 20 that is displayed in the room section 71 based on the one or more inputs received from the user through the input section 72. The inputs 74 of the input section 72 can be configured for the user to select from a limited number of options, such as a slider bar with a discrete number of options. The inputs 74 can also include blank spaces that allow for the user to select the appropriate input. The input section 72 can also include an input for the user to input the preferred measurement units, such as feet/inches or meters/centimeters.

The input section 72 provides for input of one or more aspects about the layout of the room 20. One set of inputs is directed to the dimensions of the room 20 and include the depth D, width W, and height H. Another set of inputs is related to the seating in the room and includes the number of seats 30 per row 31, the rows 31 of seats 30, a primary seat 30, a distance from the screen 40 to the primary seat 30, a position of an aisle 32 along the seats 30 (e.g., right, left, multiple aisles), and a width of the aisle 32. The seating inputs can include the size of the seats 30 and/or the relatively spacing of the seats 31. Other inputs can include a height of a riser 26, and a depth of the riser 26.

The input section 72 also provides for one or more inputs related to the video setup. Input options can include but are not limited to type of display (e.g., flat panel TV, projector), an aspect ratio (e.g., 16:9, 2.4:1), a desired size of the screen 40, and an immersion level.

The input section 72 provides for one or more inputs directed to the audio setup for the room 20. Inputs include but are not limited to an includes a type of front speakers 50 (e.g., in wall, box), type of side speakers 51 (e.g., in wall, box, none), type of rear speakers 52 (e.g., in wall, box, none), number of subwoofers 53 (e.g., one, two), and number of ceiling speakers 54 (e.g., two, four, six).

In one example, the server 100 requires an input for each of the queried inputs 74. In other examples, the server 100 generates the room 20 based on the inputs 74 that are received. The server 100 uses predetermined values for missing inputs to generate the room 20.

The control section 73 includes one or more control settings 75 for the user to see different aspects generated by the server 100. One control setting 75 displays of one or more room dimensions, such as a width of a row 31 of seat 32 or the dimensions of the screen 40. Another control setting 75 sets the illumination level of the room 20 (e.g., full lights, no lights). A control setting 75 displays a sound envelope that is emitted from one or more of the speakers 50, 51, 52, 53, 54. The various control settings 75 can be displayed individually or in combination with one or more other settings. The control settings 75 can also provide for generating the room 20 from different views, including a perspective view (FIG. 2), a top view (FIG. 3), and a view from the primary seat 30. Control settings 75 can also include different zoom levels.

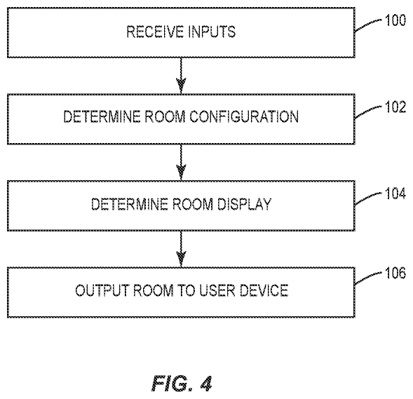

FIG. 4 illustrates a method of generating the graphical user interface that includes a room 20 for display on a user device 160. The server 100 receives inputs from the user regarding aspects of the room 20 (block 100). The server 100 determines aspects of the room 20 based on the inputs (block 102). The server 100 determines the image of the room 20 (block 104) and outputs the interface to the user device 160 (block 106).

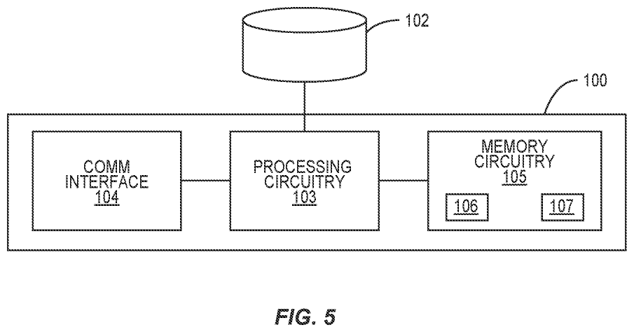

FIG. 5 illustrates a server 100 configured to calculate the room 20 and generate the corresponding images. The server 100 includes processing circuitry 103 that includes one or more microprocessors, microcontrollers, Application Specific Integrated Circuits (ASICs), or the like, configured with appropriate software and/or firmware. A computer readable storage medium (shown as memory circuitry 105) stores data and computer readable program code 106 that configures the processing circuitry 103 to implement the generation techniques. Memory circuitry 105 is a non-transitory computer readable medium and may include various memory devices such as random access memory, read-only memory, and flash memory. Communications interface 104 includes communications circuitry that connects the server 100 to the network 150. Database 102 stores information accessed by the processing circuitry 103 to generate the room 20. The database 102 is stored in a non-transitory computer readable storage medium (e.g., an electronic, magnetic, optical, electromagnetic, or semiconductor system-based storage device). The database 102 can be local or remote relative to the server 100. In one example, the server 100 does not include a database 102 and uses just data stored at the memory circuitry 105.

A rule set 107 is further stored in one or both of the memory circuitry 105 and database 102. The rule set 107 covers the dimensional aspects of the room 20 and the spacing between components. The rule set 107 can include one or more of a minimum spacing between components, a maximum spacing between components, and an optimal spacing between components. Examples of rules from the rule set include but are not limited to: the distance between the primary seat 30 and the screen 40; the distance between the front speakers 50, side speakers 51, and rear speakers 52; a distance between the projector 41 and the screen 40. In one example, the rule set 107 is a set of algorithms used by the processing circuitry 103 based on one or more of the room dimensions and components. In another example, the rule set 107 is provided from one or more of the manufacturers of the components and provide for audio and/or visual effects for the room 20.

The server 100 is configured to calculate the placement of the components within the room 20 to provide for one or more enhanced video and audio aspects. Calculations include sightline calculations for one or more of the seats 30 to provide for an unobstructed view of the screen 40. One sightline calculation includes a height of the screen 40 above the floor 24 to provide for sightlines for each of the seats 30. In one example with a single row 31 of seats 30, the bottom edge of the screen 40 is positioned thirty (30) inches above the floor 24.

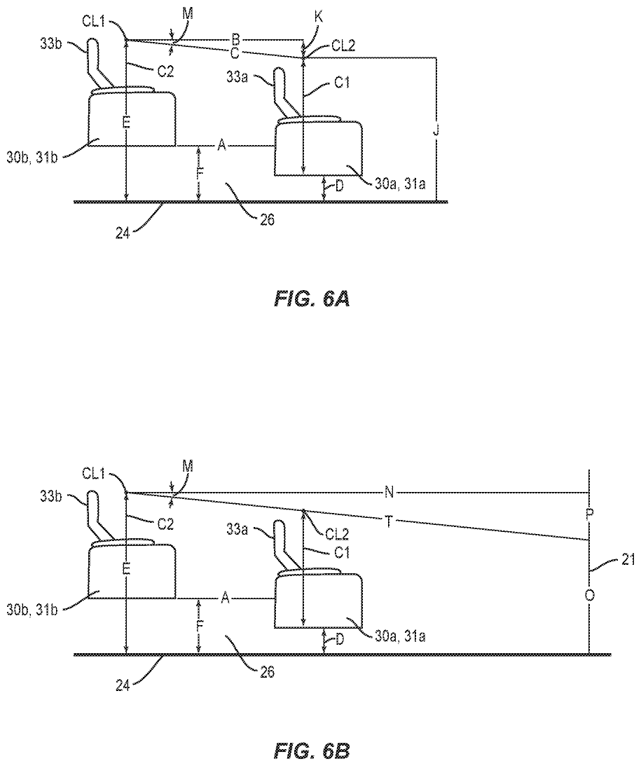

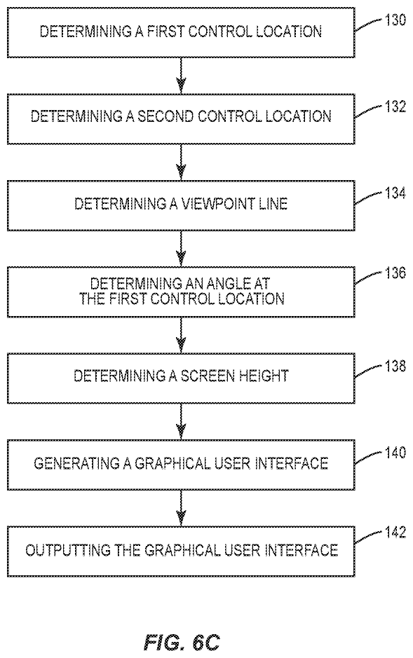

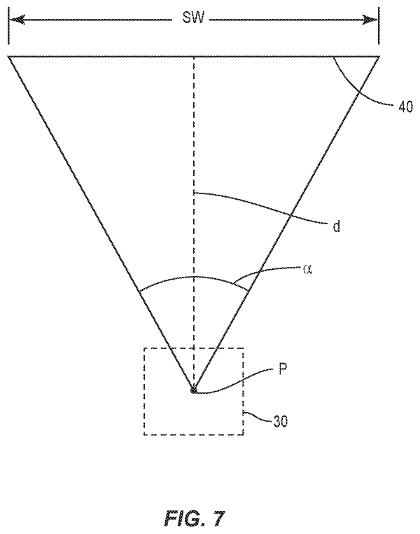

For rooms 20 with multiple rows 31, the server 100 calculates the sightlines using the rear two rows 31 (i.e., the two rows closest to the back wall 22). FIGS. 6A and 6B illustrates an example of calculations performed by the server 100 to calculate the sightlines for a room 20. These calculations include the following inputs from the user:
#Rows of Seats
Riser Height
Riser Depth (A)
Primary Row
Primary Viewing Distance (d)

FIG. 6A illustrates a schematic diagram of the back two rows 31a, 31b of seats 30a, 30b in the room 20. Each row 31a, 31b can have various numbers of seats 30a, 30b based on an input from the user. The calculations for the sightlines are based on the position of the rear-most viewing seat relative to the position of the one or more seats in front. The seats 30 in the rows 31 can be aligned at various arrangements. In one example, each of the seats 30a, 30b in the row 31a, 31b are aligned an equal distance from the front wall 21. In another example, the seats 30 in a row 31 are different distances away from the front wall 21, such as in a rounded or curved seat arrangement, or a seat arrangement with an L-shaped row 31.

For each of the seats 30a, 30b, an expected position of a viewer seated in the seat is calculated. The server 100 calculates a position of the viewer's head while seated and establishes the position as a centerline for the seats 30a, 30b. Seat 30a in the front row 31a has a calculated centerline C1 and seat 30b of the second row 31b has a centerline C2. The position of the centerlines C1, C2 within the seats 30a, 30b can be the same or can be different. In one example, the server 100 calculates the centerlines C1, C2 based on a distance from a back edge of the seats 30a, 30b. In one example, the centerline C1 is calculated as being twelve (12) inches from the back edge 33a. Centerline C2 is calculated as being sixteen (16) inches from the back edge 33b. In one example, the dimensions of the seats 30a, 30b are input by the user. In another example, the dimensions are estimated based on a predetermined size for seats 30.

The sightline calculations are based on the available information for the server 100. This includes user input and/or predetermined data stored at the server 100. Based on this information, the server 100 calculates the following dimensions as shown in FIG. 6A:

B=Riser depth(A)−4 (Eq. 1)

D=(rows−2)×riser height (Eq. 2)

F=(rows−1)×riser height (Eq. 3)

E=F+43 (Eq. 4)

J=D+48 (Eq. 5)

These calculations include a determination of a first control location CL1 which is where a viewer's eyes are located when seated in seat 30b. Point CL1 is calculated as being the distance E above the floor 24. In one example, the value 43 used when calculating E is the expected eye height of a user that is seated in the seat 30. The calculations also include a determination of a second control location CL2 which is a top of a viewer's head that is seated in seat 30a. CL2 is a distance J above the floor which accounts for any riser, an expected height of a viewer seated in seat 30a, and a hedge amount. In one example, the expected height is forty-six (46) inches and the hedge amount is forty-eight (48) inches. The position of point SH is relevant to the sightline of the viewer seated in the back row 31b.

Additional sightline calculations are generated by the server as illustrated in FIGS. 6A and 6B:

K=E—J (Eq. 6)

N=((#rows—primary row)×riser depth)+primary viewing distance (Eq. 7)

C=square root(B²+K²) (Eq. 8)

M=arcsin K/C (Eq. 9)

T=N/cosineM (Eq. 10)

P=square root(T²−N²) (Eq. 11)

O=E−P (Eq. 12)

The sightline calculations described above and illustrated in FIGS. 6A and 6B are calculated to provide unobstructed views of the screen 40 by viewers seated in each of the seats 30. The calculations generated the distance the bottom of the screen 40 is positioned above the floor 24.

N is a calculation of the distance from the screen 21 to the eyes of the farthest back viewer. This allows for the calculation of the value M which is the calculated viewing angle of the back viewer to see over the other rows 31 and viewers. The calculation of N includes the primary row to be input by the user. For example, in a room 20 which three rows 31 and the second row is the primary viewing position, the calculation uses the distance to the primary viewing row and adds the riser depth to calculate the distance to the viewer of the farthest back seat. In an example with three rows and the back row input as the primary viewing position, the calculation results in N being equal to the primary viewing distance.

### Example 1: The Sightline Calculations Performed by the Server 100 Use the Following Inputs from the User (Inches are Used for Units of Measurements in this Example)

Riser depth=78 inches
Riser height=12 inches
Rows=2
Viewing distance to primary seats=271 inches
Primary row=2

B: 78−4=74

F: (2−1)×12=12

D: (2−2)×12=0

E: 12+43=55

J: 0+48=48

K: 55-48=7

N: (2−2)×78+271=271

C: sq rt(74²+7²)=74.33

M: arcsin 7/74.33=0.094

T: 271/cosine 0.094=272.21

P: sq rt(272.21²−271²)=25.64

Q: 55−25.64=29.36

In this example, the bottom edge of the screen 40 should be placed about twenty-nine (29) inches above the floor 24. In one example, the screen 40 includes a frame. The server 100 further computes the size of the frame and adjusts the distance above the floor 24.

FIG. 6C illustrates a flowchart of a method of generating an of an interactive graphical user interface that represents a room 20 for viewing on a user device 160. The method includes determining a first control location CL1 (block 130). The first control location CL1 defines an eye height of a back viewer sitting in a back seat 30b. The eye height is calculated as being a first distance above the floor 24.

A second control location CL2 is determined that is above a head of a front viewer sitting in a front seat 30a (block 132). The second control location CL2 is a combination of an amount the head of the front viewer is above the floor 24 when sitting in the front seat 30a plus a safety variable distance.

A viewpoint line is determined that extends between the first control location CL1 and the screen 40 (block 134). The viewpoint line is perpendicular to the screen 40. An angle is determined at the first control location CL1 (block 136). The angle is formed between the viewpoint line and a straight line that extends between the first control location CL1 and the second control location CL2. A screen height is determined that is a distance between the floor 24 and a bottom edge of the screen 40 (block 138). The screen height is determined based on the angle and a distance between the first control location CL1 and the screen 40. An interactive graphical user interface 70 is generated (block 140). The interface 70 represents the room 20 and includes the back seat 30b, the front seat 30a, and the screen 40 mounted to the front wall 21 with a bottom of the screen 40 positioned above the floor 24 by the screen height. The graphical user interface 70 is output to a display 161 of a user device 160 (block 142).

The server 100 also calculates an immersion level for a viewer seated at a primary seat 30. The immersion level is the extent the screen 40 fills the viewer's field of vision. In one example, an average immersion level fills a moderate level of a viewer's field of vision. A higher immersion level fills the majority of a viewer's field of vision. The server 100 calculates different immersion level based on the horizontal viewing angle taken from a point P at the primary seat 30. In the event the user does not specify the primary seat P, the server 100 will use a default seat 30. In one example, the primary seat P is the middle seat 30 of the back row 31. In another example, the primary seat is the middle seat 30 of the front row 31. In another example with an even number of seats in the primary row 31, the primary position is a midpoint between the middle two seats 30 of the row 31.

FIG. 7 schematically illustrates a horizontal viewing angle α for point P from a primary seat 30 that is a distance d away from the screen 40. The screen 40 includes a width sw. The viewing angle α is calculated as follows:

viewing angleα=(tan⁻¹(sw/2)/d)×2 (Eq 13)

### Example 2: A Viewing Angle for a Screen with a Width of 40 Inches with a Primary Viewing Point that is 144 Inches Away from the Screen

Viewing angle α=(tan⁻¹(40/2)/144)×2=26.5

In one example, the server 100 stores immersion level ratings to grade the design of the room 20. The ratings are based on the horizontal viewing angle and can have different levels (e.g., low, average, high, extreme). Tables 1 and 2 illustrate examples of the rating for an immersion level based on the horizontal viewing angle for different types of screens 40.

TABLE 1
(screen aspect ratio of 16:9)

| Greater than | Equal to or less than | Rating |
|---|---|---|
| 0° | 28.4° | Level 1 (Low) |
| 28.4° | 38° | Level 2 (Average) |
| 38° | 41.4° | Level 3 (Higher) |
| 41.4° | 180° | Level 4 (Extreme) |

TABLE 2
(screen aspect ratio of 2.4)

| Greater than | Equal to or less than | Rating |
|---|---|---|
| 0° | 37° | Level 1 (Low) |
| 37° | 44.4° | Level 2 (Average) |
| 44.4° | 52.4° | Level 3 (Higher) |
| 52.4° | 180° | Level 4 (Extreme) |

In one example, the input by the user requires the horizontal viewing angle to meet at least a predetermined rating. For example, the server 100 will show an error message in the event the user input results in a horizontal viewing angle of Level 1. In another example, the server 100 calculates the horizontal viewing angle based on the user input and outputs the rating to the user informing them of the rating but does not provide an error message regardless of the calculated rating.

The server 100 also calculates specifications for one or more of the speakers including the front speakers 50, side speakers 51, rear speakers 52, subwoofer 53, and ceiling speakers 54. The speaker channels and type of speakers (e.g., model number, manufacturer) are input from the user. In one example, the server 100 stores default channels and speakers in the event no input is received from the user.

In one example as illustrated in FIG. 2, three front speakers 50 are included in the room 20. In one example, if the screen 40 is not acoustically transparent, the server 100 calculates the distance between the two outer front speakers 50 as equaling 1.04 times the distance d from the screen 40 to the primary seat 30 (i.e., 1.04×d). Regardless of the calculation, the distance between the two front speakers 50 is calculated as being not wider than the width W of the room 20 and not narrower than the screen width ws. If the screen 40 is acoustically transparent, the distance between the two outer front speakers 50 is constrained to no wider than the width of the screen ws and inside a frame of the screen 40.

The server 100 calculates the positioning of the side speakers 51. The side speakers 51 are positioned on the lateral side walls 23 equal distances away from the front wall 21. When there is a single row 31 of seats 30, the side speakers 51 are spaced away from the front wall 21 a distance that is six (6) inches less than the distance d between the point P on the primary seat 30 (i.e., placement=d−6). In a room 20 with two rows 31, the side speakers 51 are positioned equal distances between the two rows 31. In a room 20 with three rows 31, the speakers 51 are calculated as being positioned the same distance as the distance from the screen 40 to the center of the second row 31.

The server 100 can also calculate the positioning of the side speakers 51 using different calculations. If there is only one row 31 of seats 30, the side speakers 51 are positioned perpendicular to the main viewing position P. The side speakers 52 can also be moved forwards towards the front wall 21 six (6) inches. That is, the side speakers 51 are positioned 90° from the primary viewing position P (to the left and right) and forward 6″ toward the front wall 21. This positioning that is slightly forward from the primary viewing position P provides for the speakers 51 to be slightly forward so that persons adjacent to a person in the primary point P does not block the sound from the speakers 51. In another example, instead of moving forward six (6) inches, the speakers 51 are moved forward 5°. In one specific example, the speakers 51 are placed at 85 instead of 90°. When there are two rows 31a, 31b, the side speakers 51 are positioned equidistant between the first row 31a and the second row 31b. This equal distancing enable both rows 31a, 31b to share equally in the side sound. When there are three rows 31a, 31b, 31c, the side speakers 51 are positioned perpendicular to the middle row 31b. This positioning provides for all three rows 31a, 31b, 31c to share the sound as best as possible.

The server 100 calculates the position of the side speakers 51 above the floor 24 as a predetermined value plus an average height of the risers 26. In one example, the server 100 calculates the height as fifty (50) inches plus the average height of the risers 26 (i.e., vertical distance=50+avg. riser height). In another example, the side speakers 51 are positioned at a fixed height above the riser 26 that is below them. For example, side speakers 51 at a second row 31 of seats 30 would be positioned fifty (50) inches above the riser 26 of the second row 31. Side speakers 51 next to the third row 31 would be positioned fifty (50) inches above the riser 26 of the third row 31.

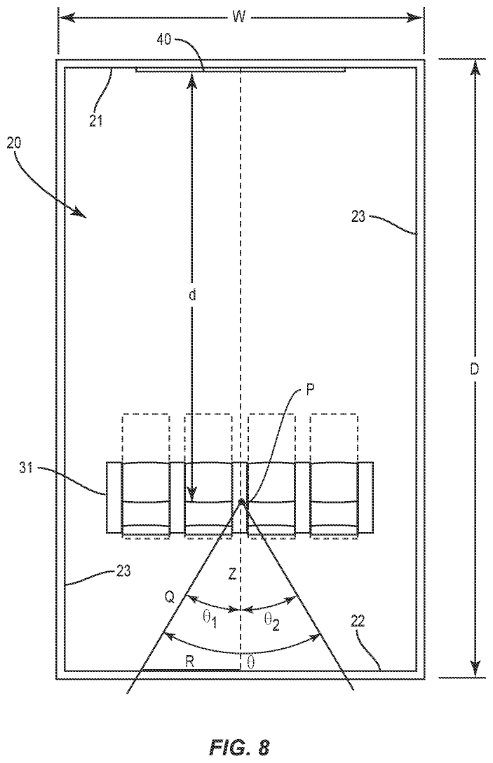

The rear speakers 52 are mounted at the back wall 22. The number of rear speakers 52 can vary depending upon the desired acoustic performance. FIG. 8 illustrates the calculations performed by the server 100 for placement of a pair of rear speakers 52. The calculations are based on user input that includes the depth D and width W of the room 20, and the primary distance d between the point P at the primary seat 30 and the screen 40. As illustrated in FIG. 8, the server 100 further receives user input regarding the angular range θ of the rear speakers 52 at point P. The angular range θ is defined by the combination of θ1 and θ2. In one example, each of θ1 and θ2 can be equal to equal predetermined values (e.g., 30°, 45).

The server 100 calculates the following values:

Value Z is calculated as the distance between the back wall 22 and the primary viewing distance d.

Z=D−d (Eq. 14)

Value Q is calculated as the distance along the angular range between the primary point P and the back wall 22. For this calculation, the angle θ1 is converted to radians.

Q=Z/cosineθ1 (Eq. 15)

R=sq.rt Q²−Z² (Eq. 16)

G=(W/2)−12 (Eq. 17)

The calculation for the distance between the rear speakers 52 is:

If R<36,distance=36; (Eq. 18)
Otherwise, If R<G, distance=R; if R>G, distance=G

### Example

The following inputs are received from the user (the units are in inches): Room depth (D)=180; Room width (W)=120; Primary viewing distance (d)=120; the room layout includes side and rear speakers; the angle θ1 is 30° and θ is 30°.

Z=D−d;Z=180−120=60

θ1=30° which equates to 0.523

Q=Z/cosineθ1;Q=60/cosine0.523=69.28

R=sq.rt Q²−Z²;R=sq rt69.28²−60²=34.64

G=(W/2)−12;G=120/2−12=48

Distance=36

The calculated amount is the distance between the two rear speakers 52. In one example, the two speakers 52 are centered along a centerline of the room 20 (i.e., the middle of the width W) with each of the speakers 52 an equal distance away from the centerline. In another example, the speakers 52 are centered along a position of the primary spot P, which may or may not be aligned along the centerline of the room.

The calculations for placement of the rear speakers 52 can be dependent upon one or more other components in the room 20. In one example, if the room 20 includes side speakers 51, then the rear speakers 52 are moved closer to the centerline of the room 20. For example, the rear speakers 52 are positioned 30° from the centerline in each direction (i.e., θ1 and θ2 are each 30°). This positioning of the rear speakers 52 provides a more immersive experience. If the room 20 does not include side speakers 51, then the rear speakers 52 are moved out wider (e.g., θ1 and θ2 are each 45°) to accommodate for the lack of side speakers 51. In one example, this positioning of the width based on the existence of the side speakers 52 is calculated regardless of any contradictory input. In another example, the user is able to over-ride the positioning and select the desire angular positions of the rear speakers 52.

The server 100 calculates the rear speakers 52 positioned a distance above the floor 24 an amount equal to a predetermined value plus a height for the risers 26. In one example, the server 100 calculates the distance as fifty (50) inches plus a sum of all the heights of the risers 26. This positions the rear speakers 52 at fifty (50) inches above the back row riser.

The server 100 also calculates the position of the ceiling speakers 54. Various numbers of ceiling speakers 54 can be incorporated into the room 20. In one example, the ceiling speakers 54 are Dolby Atmos speakers.

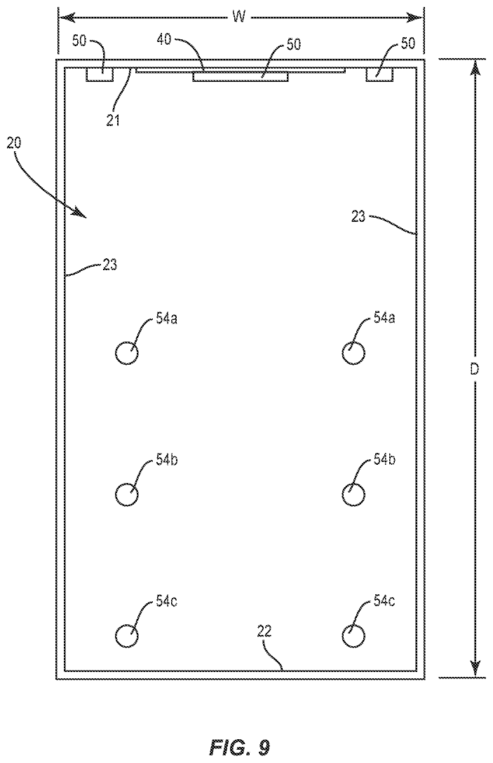

FIG. 9 illustrates an example in which the server 100 calculates the positioning of three pairs of ceiling speakers 54. As illustrated in FIG. 9, these include a first pair 54a that are closest to the front wall 21, a middle pair 54b, and a rear pair 54c. The number of ceiling speakers 54 in the room 20 is received from the user. In the event fewer ceiling speakers 54 are input from the user, the server 100 uses a limited number of the calculated positions. For example, if the user inputs just a single pair of ceiling speakers 54, the server 100 positions the single pair at 10° forward of the primary viewing position. If the user inputs two pairs of speakers 54, the server 100 uses the positioning for the front and rear pairs 54a, 54c.

The server 100 calculates the distance between each of the pairs 54 (e.g., 54a, 54b, 54c) across the width W of the room 20 to be the same as the distance between the two outer front speakers 50. In one example, the distance between the pair 54 is 1.04 the distance d measured between the screen 40 and the primary point P. The distance between the pair 54 is not wider than the width W of the room 20 or narrower than the distance between the left and right front speakers 50. When an acoustically transparent screen 40 is used the pair 54 can be as wide as the screen 40 but inside a frame that extends around the screen 40. In another example, the front speakers 54a are positioned in front of the first row 31a, the rear speakers 54c are positioned behind the rear row 31c. The distance across the width W of the room positions the rear speakers 54 outward beyond the seats 30 (i.e., left speakers 54 are positioned to the left of the seats 30 and the right speakers 54 are positioned to the right of the seats 30).

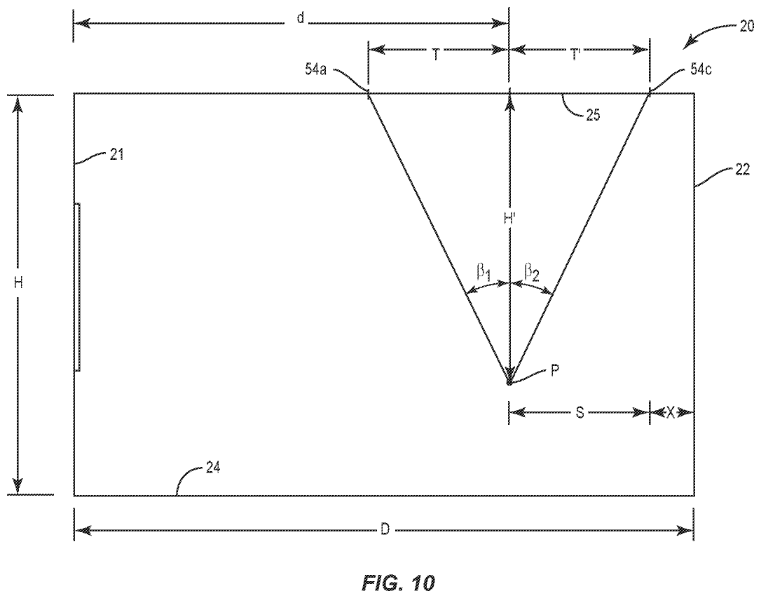

The server 100 also calculates the position of the ceiling speakers 54 along the depth D of the room 20. FIG. 10 illustrates an example that includes two pairs of speakers 54a, 54c. The speakers 54a, 54c are equally spaced apart about the primary point P that is a distance d from the front wall 21. A buffer X is set from the back wall 22. The calculations by the server 100 prevent the rear speakers 54c from being positioned within the buffer X. In one example, the buffer X represents a space in which the speakers 54c cannot be physically positioned due to the architecture of the room 20 and/or the house in which the room 20 is located.

A line H′ extends between the ceiling and the point P. The line H′ is perpendicular to the ceiling 25. The length of H′ measured between the ceiling 25 and point P is the calculated as the height H of the room 20 less a predetermined amount. In one example, the predetermined amount is the distance CL1 which is the calculated position of the viewer's ears. In another example, predetermined distance is a percentage of the height H of the room (e.g., 0.25(H), 0.4(H)). In another example, the predetermined distance is forty-one (41) inches. In another example, the predetermined distance is the predetermined distance plus the height of the riser 26 at the primary point P.

The speakers 54a, 54c are equally spaced from the point P along the depth D. The first pair 54a is positioned at an angle β1 relative to the line H′ that extends through the primary point P. The second pair 54c is positioned at an equal angle β2 relative to the line H′.

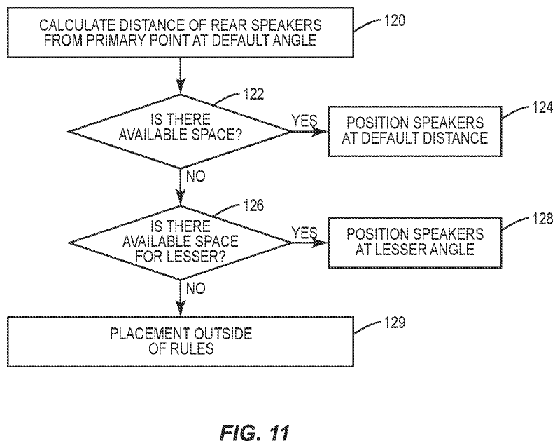

FIG. 11 illustrates the calculations performed by the server 100 in placing the speakers 54a, 54c in the room 20. The server 100 calculations the distances T, T′ for a default angular position (block 120). In one example, the default setting for each pair of speakers 54a, 54c is 45° (i.e., each of β1 and β2 are at 45). The server 100 calculates the position of the speakers 54a, 54c to be symmetrical about the primary point P.

The server 100 determines if there is adequate space in the room 20 for the default position (block 122). The default positioning is available when the distance S defined between the primary point P and the buffer zone X defined along the depth D is greater than the distance T′ defined as the distance between the primary point P and the position of the speakers 54c. If the default positioning is available, the speakers 54a, 54c are set at this distance with the default angular positioning from the primary point P (block 124).

If there is not space for the default positioning, the server 100 calculates the distance for positioning the speakers at one or more lesser angular positions (block 126). This includes calculating the distances down to a predetermined minimum angular position at which the audio experience in the room is not adequate to what the sound engineers intended when producing the content. In one example, the predetermined minimum angular position is 30°. The server 100 positions the speakers 54a, 54c at the largest available angular position that is above the predetermined minimum (block 128). For example, the server 100 will position the speakers at an angle of 40° when the default angular position of 45 is not available, and the 40° is the largest angular position that positions the speakers 54c away from the buffer X.

If the server 100 calculates that there is not space available for the minimum distance, the server 100 provides an indication to the user (block 129). The indication may include an error message that prevents the placement of the speakers 54a, 54c. In another example, the user can input an acknowledgement of the error message and that the speakers 54a, 54c are positioned outside of a rule.

In one example, the front and rear speakers 54a, 54c are centered about the line H′. Each of the speakers 54a, 54c is positioned an equal distance away from the line H′. The server 100 can limit the angular range between the speakers 54a, 54c within a range of 60°-90° with each of β1 and β2 being between 30°-45°.

Another example of placement of the ceiling speakers 54 is positioning the rear speakers 54c to be closer than the front speakers 54a. This can occur in one example when the rear row 31 of seats 30 get very close to the back wall 22. This close positioning contracts the rear ceiling speakers 54c to be closer to the seats 30 and positioned at the buffer area X but still have the front ceiling speakers 54a stay farther forward. The front speakers 54a are in front of the first row 31a of seats 30b and the rear speakers 54c are behind the last row 31c of seats 30c. The seats 30 may not be equidistant from the main viewing point but ensures that the various seats 30 get the proper audio experience.

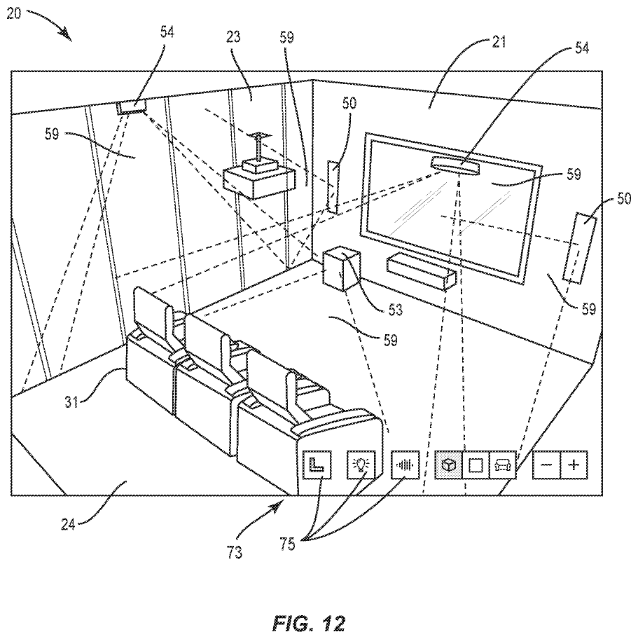

The server 100 is further configured to generate sound envelopes 59 for one or more of the speakers 50, 51, 52, 53, 54. As illustrated in FIG. 12, the sound envelopes 59 visually illustrate the dispersion of the sound from the speaker and into the room 20. This visual representation can assist a user in creating the desired sound effects for the room 20. In one example, the sound dispersion is activated based on an input through a control input 75 on the control section 73 of the generated display. The user can toggle the sound dispersion setting on and off as desired. In one example, the settings provide for a sound envelope 59 to be displayed for each of the speakers in the room 20. Additionally or alternatively, the user is able to turn the sound envelope 59 on or off individually for each speaker in the room 20. This individual setting for each speaker provides for a user to see the sound of a single speaker. In another setting, the sets of speakers can be toggled on or off. For example, just the front speakers 50 are displayed with a sound envelope 59 with the other speakers not having a sound envelope 59. This provides for the user to visually see the effect of the set of specific speaker components.

For each of the various components in the design of the room 20, the server 100 can receive changes to one or more of the inputs. For example, the server 100 generates a display for a room 20 with three rows 31 of seats 30. After the room 20 is displayed by the user, the server 100 receives a change that includes just two rows 31. The server 100 recalculates the settings of the various components and generates an updated room 20 that can be displayed by the user. The one or more new inputs are entered by the user by toggling through one or more of the values shown in the input section 72 on the generated image. Additionally or alternatively, inputs can be entered by the user positioning a curser on the one or more components displayed in the room 20 and dragging the component to the new location.

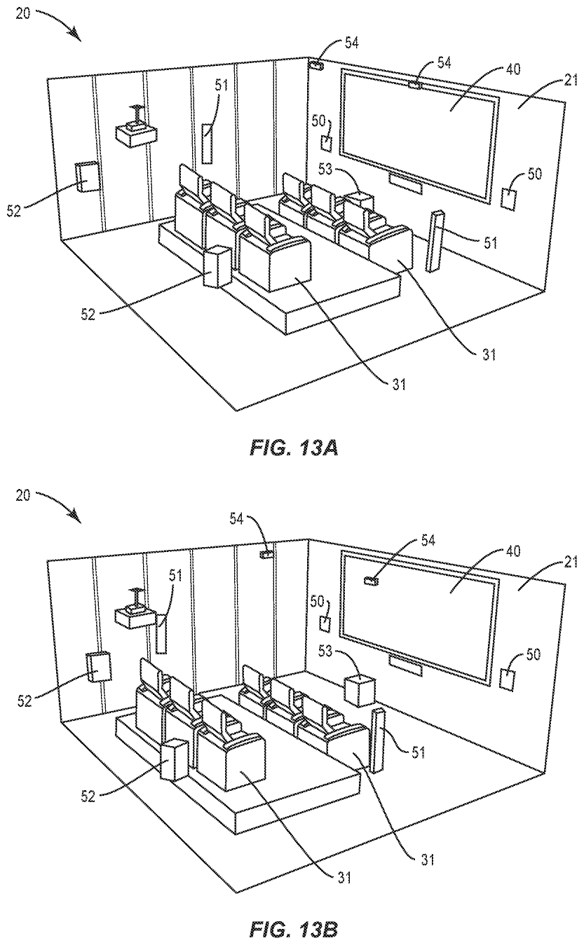

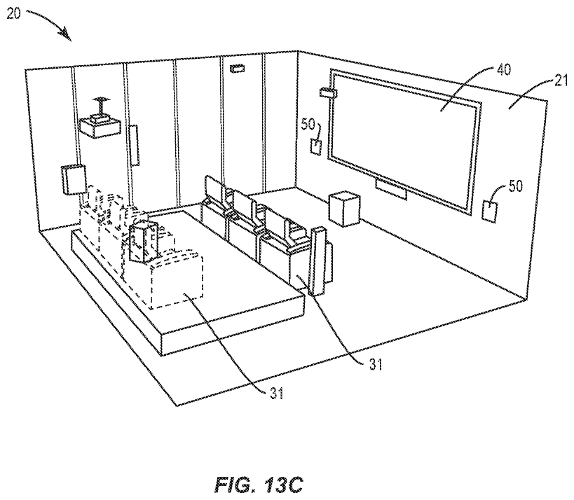

FIG. 13A illustrates a room 20 generated by the server 100 and having a first layout. The positioning of the various components is based on one or more inputs received by the server 100. The room 20 includes the rows 31 of seats 30 positioned a first distance away from the front wall 21. The server 100 calculates the placement of the speakers 50, 51, 52, 53, 54.

FIG. 13B illustrates an updated room 20 based on one or more inputs from the user that change the configuration. In this example, the user input positions the rows 31 farther away from the front wall 21. The server 100 receives the input of the change in positioning of the rows 31 and calculates the new positioning for each of the components. The new layout for the room 20 is generated by the server 100 for display by the user. As seen in the comparison of FIGS. 13A and 13B, the change in the positioning of the rows 31 causes noticeable changes in the positioning of the side speakers 51 and the ceiling speakers 54.

The server 100 recalculates the positioning of the various components in the room 20 based on the one or more new inputs. In the event that the user attempts to position a component at a location that is outside of a rule, the server 100 notifies the user of the rule. FIG. 13C illustrates an example of a notification that includes an error message generated by the server 100 in response to receiving one or more inputs that violate one or more rules. In this example, the received input attempts to position the back row 31 too far away from the screen 40. This position would result in one or more of the rules being out of range. In this specific example, the server 100 generates an image that highlights the one or more components that are in violation (e.g., the rows 31 are highlighted to show non-compliance). One or more error messages can also be generated to be displayed that describe the one or more rule violations. In one example, the error message includes a description of the error (e.g., back row 31 too far from screen 40) and a description of how to correct the error.

In one example, the server 100 generates an image with the one or more components at the violated position. In another example, the server 100 positions the one or more violating components at the maximum allowable position according to the one or more rules but does not generate an image with the component at the calculated position based on the one or more inputs. For example, if the server 100 receives an input to position a back row 31 within six (6) inches of the back wall 22 but a rule prevents placement closer than twelve (12) inches, the server 100 generates an image of the room 20 with the back row 31 at the inputted position.

The server 100 calculates the positioning of the various components. The calculations can be based on independently positioning each of the components regardless of the other components. The server 100 can also calculate the position based on their inter-relatedness with other components in the room 20. For example, the positioning of the rear speakers 52 is set based on whether there are side speakers 51. The positioning of the ceiling speakers 54 is based on the number of rows 31 of seats 30. This inter-relatedness of components provides for the server 100 to calculate an accurate representation of the mastered audio content.

The present invention may be carried out in other ways than those specifically set forth herein without departing from essential characteristics of the invention. The present embodiments are to be considered in all respects as illustrative and not restrictive, and all changes coming within the meaning and equivalency range of the appended claims are intended to be embraced therein.

What is claimed is:

1. A method of generating an of an interactive graphical user interface that represents a room for viewing on a user device, the room comprising a floor, a front wall, and a screen mounted to a front wall, the method comprising:
determining a first control location defining an eye height of a back viewer sitting in a back seat with the eye height comprising a first distance above the floor;
determining a second control location that is above a head of a front viewer sitting in a front seat and positioned between the back seat and the screen, the second control location comprising a combination of an amount the head of the front viewer is above the floor when sitting in the front seat plus a safety variable distance;
determining a viewpoint line that extends between the first control location and the screen with the viewpoint line being perpendicular to the screen;
determining an angle at the first control location formed between the viewpoint line and a straight line that extends between the first control location and the second control location;
based on the angle and a distance between the first control location and the screen, calculating a screen height between the floor and a bottom edge of the screen;
generating an interactive graphical user interface that represents the room and comprises the back seat, the front seat, and the screen mounted to the front wall with a bottom of the screen positioned above the floor by the screen height; and
outputting the graphical user interface to a display of a user device.

2. The method of claim 1, wherein determining the first control location comprises adding a back seat height plus forty-three (43) inches.

3. The method of claim 2, further comprising determining the seat height of the back seat comprises:
seat height=(rows−1)(riser height)
where rows equals the numbers of rows and riser height equals a height of a riser above the floor.

4. The method of claim 3, wherein determining the second control location comprises adding a front seat height plus forty-six (46) inches.

5. The method of claim 4, wherein the safety variable distance comprises two (2) inches.

6. The method of claim 1, wherein determining the second control location comprises:
second control location=(rows−2)(riser height)+46+2
where rows equal the number of rows and riser height equal a height of a riser above the floor.

7. The method of claim 1, further comprising determining the first control location along the length of the room as a first predetermined distance from a back of the back seat and determining the second control location along the length of the room as a second predetermined distance from a back of the front seat.

8. The method of claim 1, further comprising:
determining positions of speakers in the room and sound envelopes that are emitted from the speakers;
generating the interactive graphical user interface comprising the sound envelopes; and
outputting the graphical user interface with the sound envelopes to the display of the user device.

9. The method of claim 1, further comprising:
receiving a first input from the user device comprising an immersion distance of a primary viewing point away from the screen along the length;
receiving a second input from the user device comprising a display type of the screen; and
determining an immersion level based on the immersion distance and the display size.

10. A server configured to generate an interactive graphical user interface that represents a room, the room comprises a floor, a front wall, a back wall, a ceiling, and a screen mounted to a front wall, the server comprising:
memory circuitry configured to contain:
a length of the room measured between the front and back walls;
a primary viewing point along the length of the room, the primary viewing point positioned a first distance along the length away from the screen and a second distance below the ceiling;
a buffer region that extends along the length outward from the back wall;
processing circuitry configured to:
calculate a position of rear ceiling speakers along the length at an angle formed between a perpendicular line that extends from the ceiling to the primary viewing point and a first angle line;
when the position is outside of the buffer region, locate the rear ceiling speakers at the position;
when the position is within the buffer region, reduce the angle and recalculate the position of the rear ceiling speakers to outside of the buffer region;
calculate a distance between the perpendicular line and the position;
position the front ceiling speakers at a front location along the length that is in front of the perpendicular line by the distance;
generate a graphical user interface of the room that comprises a row of seats at the primary viewing point, the screen mounted to the front wall, the rear ceiling speakers at the position behind primary viewing point, and the front ceiling speakers at the front location; and
output the graphical user interface to a display of a user device.

11. The server of claim 10, further comprising the processing circuitry configured to center the front ceiling speakers and the back ceiling speakers along a centerline of a width of the room.

12. The server of claim 10, further comprising the processing circuitry configured to position the front ceiling speakers and the back ceiling speakers apart within a range of between 60-90°.

13. The server of claim 10, further comprising the processing circuitry configured to space each of the front ceiling speakers and the back ceiling speakers an equal distance away from the primary viewing point along the length.

14. The server of claim 10, further comprising the processing circuitry configured to:
determine sound envelopes that are emitted from the front ceiling speakers and the back ceiling speakers;
generate the graphical user interface comprising the sound envelopes; and
output the graphical user interface with the sound envelopes to the display of the user device.

15. The server of claim 10, further comprising the processing circuitry configured to:
receive a first input from the user device comprising an immersion distance of a primary viewing point away from the screen along the length;
receive a second input from the user device comprising a display type of the screen; and
determine an immersion level based on the immersion distance and the display type.

16. A server configured to generate an interactive graphical user interface that represents a room, the room comprises a floor, a front wall, a back wall, a ceiling, and a screen mounted to a front wall, the server comprising:
memory circuitry; and
processing circuitry configured to:
determine a first control location defining an eye height of a back viewer sitting in a back seat with the eye height comprising a first distance above the floor;
determine a second control location defining a spot above a head of a front viewer sitting in a front seat and positioned between the back seat and the screen, the second control location comprising a combination of an amount the head of the front viewer is above the floor when sitting in the front seat plus a safety variable distance;
determine a viewpoint line that extends between the first control location and the screen with the line being perpendicular to the screen;
determine an angle at the first control location formed between the viewpoint line and a straight line that extends between the first control location and the second control location;
based on the angle and a distance between the first control location and the screen, calculate a screen height between the floor and a bottom edge of the screen;
generate an interactive graphical user interface that represents the room and comprises the back seat, the front seat, and the screen mounted to the front wall with a bottom of the screen positioned above the floor by the screen height; and
output the graphical user interface to a display of a user device.

17. The server of claim 16, wherein the processing circuitry is further configured to:
determine positions of speakers in the room and sound envelopes that are emitted from the speakers;
generate the interactive graphical user interface comprising the sound envelopes; and
output the graphical user interface with the sound envelopes to the display of the user device.

18. The server of claim 16, wherein the processing circuitry is further configured to:
receive a first input from the user device comprising an immersion distance of a primary viewing point away from the screen along the length;
receive a second input from the user device comprising a display type of the screen; and
determine an immersion level based on the immersion distance and the display type.
